(19) United States
(12) Patent Application Publication
(10) Pub. No.: US 2026/0343809 A1
(43) Pub. Date: Oct. 29, 2026

(54) LEAK DETECTION USING A DYE AND AN ELECTROMAGNETIC RADIATION MODULATOR

(71) Applicant: Dell Products L.P., Round Rock, TX (US)

(72) Inventors: MICHAEL J. STUMPF, Cedar Park, TX (US); SANDOR TIBOR FARKAS, Round Rock, TX (US)

(21) Appl. No.: 19/192,488

(22) Filed: Apr. 29, 2025

(51) Int. Cl. H05K 7/20; G01F 23/292

(52) U.S. Cl. CPC H05K 7/20272; G01F 23/292; H05K 7/20763

(57) ABSTRACT

Devices, systems, and methods for managing leaks in a chassis of a data processing system is provided. To manage the leaks, the data processing system may include an electromagnetic stimulator, an electromagnetic detector, a modulator, and a management component. The electromagnetic stimulator may be adapted to illuminate a sample area with first electromagnetic radiation. The electromagnetic detector may be adapted measure second electromagnetic radiation to obtain at least one electromagnetic measurement. The modulator may be adapted to temporally manage the illuminating of the sample area and the measuring the second electromagnetic radiation. The management component may determine whether a liquid leak within the chassis occurred based on the at least one electromagnetic measurement. If the liquid leak occurred, performance of a remediation action may be initiated.

### FIELD

Embodiments disclosed herein relate generally to managing leaks. More particularly, embodiments disclosed herein relate to systems and methods for managing leaks in a chassis of a data processing system using a leak detector.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a diagram illustrating a data processing system in accordance with an embodiment.

FIG. 2 shows a diagram illustrating leak detection in accordance with an embodiment.

FIGS. 3A-3E show diagrams illustrating a modulator in accordance with an embodiment.

FIG. 4 shows a flow diagram illustrating a method for managing leaks in a chassis of a data processing system in accordance with an embodiment.

FIG. 5 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods, systems, and devices for managing operation of a data processing system. The data processing system may provide computer-implemented services. To provide the computer-implemented services, the data processing system may include any number and/or type of hardware components. Operation of the hardware components may facilitate various functionalities of the data processing system, thereby allowing the data processing system to provide the computer-implemented services.

However, operation of the hardware components may generate heat. To manage the heat generated by the hardware components so that the hardware components may operate as desired, a liquid cooling system may be used. To do so, a cooling liquid may be circulated within a chassis of the data processing system to dissipate at least a portion of the heat generated by the hardware components.

However, by circulating the cooling liquid through the chassis (and/or otherwise having liquid within the system), a likelihood of liquid damage may be increased within the system. For example, should the liquid cooling system leak at least a portion of the cooling liquid, the hardware components may be vulnerable to liquid damage. Consequently, such liquid damage may negatively impact the operation of the hardware components. In turn, this damage may also negatively impact the computer-implemented services provided by the data processing system.

To mitigate an impact of an occurrence of a liquid leak in the chassis of the data processing system, the data processing system may include functionality to detect leaks using a leak detector. The leak detector may be used to monitor portions of the data processing system which may have a risk of liquid leaks occurring (e.g., connection points of the cooling tubes). To do so, the leak detector may include: (i) an electromagnetic stimulator adapted to illuminate a sample area (e.g., in which the leak is likely to occur) with first electromagnetic radiation, (ii) an electromagnetic detector adapted to measure second electromagnetic radiation (e.g., generated by a dye included in the liquid in response to the illumination), (iii) a modulator, and/or (iv) a management component.

The modulator may be adapted to temporally manage the illuminating of the sample area with the first electromagnetic radiation and the measuring the second electromagnetic radiation so that the illuminating and the measuring occur asynchronously. An ability of the illuminating and the measuring to be performed asynchronously may be enabled using a dye with a sufficiently long time constant. The modulator may be implemented using a physical device and/or an electrical circuit.

For example, the modulator may physically temporally manage the illuminating and the measuring using a mechanical chopper. The mechanical chopper may include at least one opening adapted to allow the first electromagnetic radiation and the second electromagnetic radiation to traverse the mechanical chopper. The mechanical chopper may also include a motor to rotate the mechanical chopper so that the illuminating and the measuring occur at different points in time.

In another example, the modulator may electronically manage the illuminating and the measuring by selectively powering the electromagnetic stimulator and configuring operation of the electromagnetic detector. For example, a circuit may be designed to power on the electromagnetic stimulator in increments of illumination. Based on the increments, the electromagnetic detector may measure the second electromagnetic radiation (e.g., during periods in which the electromagnetic stimulator is powered off).

In doing so, contribution of the first electromagnetic radiation to the at least one electromagnetic measurement may be reduced. As a result, the at least one electromagnetic measurement may be usable to determine whether a liquid leak occurred in the chassis of the data processing system by a management component. By identifying whether the liquid leak has occurred, remediation actions may be performed to reduce an impact of the liquid leak on operation of the data processing system.

Thus, embodiments disclosed herein may provide an improved data processing system that may have an improved likelihood of detecting a liquid leak within a chassis of the data processing system. By detecting the leak, additional leaked cooling liquid may be prevented from escaping into an interior of the chassis. Consequently, the hardware components may operate as desired, and computer-implemented services may be reliably provided by the data processing system using the hardware components.

In an embodiment, a data processing system is provided. The data processing system may include: a chassis; an electromagnetic stimulator adapted to illuminate a sample area with first electromagnetic radiation, the first electromagnetic radiation adapted to cause a liquid to generate second electromagnetic radiation; an electromagnetic detector adapted to measure the second electromagnetic radiation to obtain at least one electromagnetic measurement; a modulator adapted to temporally manage the illuminating of the sample area and the measuring the second electromagnetic radiation so that the illuminating and the measuring occur asynchronously; and a management component adapted to: make a determination regarding whether a liquid leak within the chassis has occurred based on the at least one electromagnetic measurement; and in an instance of the determination where the liquid leak has occurred: initiate performance of a remediation action to mitigate impacts of the liquid leak.

The modulator may include a mechanical chopper.

The mechanical chopper may include at least one opening adapted to allow the first electromagnetic radiation and the second electromagnetic radiation to traverse the mechanical chopper; and a motor adapted to rotate the mechanical chopper to temporally manage the illuminating and the measuring.

The mechanical chopper may include: a first side through which the first electromagnetic radiation enters the mechanical chopper; and a second side through which the second electromagnetic radiation enters the mechanical chopper.

The electromagnetic stimulator and the electromagnetic detector may be positioned with the first side of the mechanical chopper, and the sample area may be positioned with the second side of the mechanical chopper.

The at least on opening may be positioned so that the first electromagnetic radiation and the second electromagnetic radiation do not traverse the mechanical chopper at a same point in time.

The modulator may be adapted to cause the illuminating to occur at a first point in time, and the measuring to occur at a second point in time.

The liquid may include a dye adapted to: interact with at least a portion of the electromagnetic radiation at the first point in time; and generate, based on the interacting, the second electromagnetic radiation during at least the second point in time.

The modulator may be adapted to temporally manage the illuminating of the sample area and the measuring the second electromagnetic radiation by selectively powering the electromagnetic stimulator and configuring operation of the electromagnetic detector.

The modulator may configure the operation of the electromagnetic detector based on the selective powering of the electromagnetic stimulator.

The electromagnetic detector may be adapted to measure the first electromagnetic radiation and the second electromagnetic radiation to generate a measurement signal, the measurement signal not distinguishing between contributions of the first electromagnetic radiation and the second electromagnetic radiation to the generated measurement signal.

The illuminating and the measuring may occur asynchronously to obtain an instance of the generated measurement signal that has a reduced level of contribution by the first electromagnetic radiation.

In an embodiment, a method for managing leaks in a chassis of a data processing system is provided.

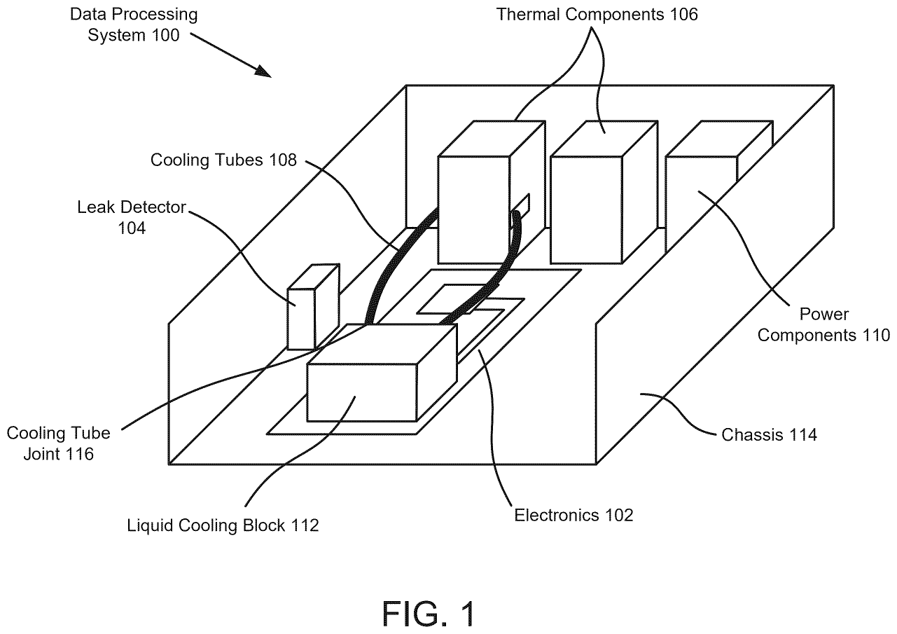

Turning to FIG. 1, a block diagram illustrating a system in accordance with an embodiment is shown. The system shown in FIG. 1 may provide any quantity and type of computer-implemented services. To provide the computer-implemented services, the system of FIG. 1 may include data processing system 100.

Data processing system 100 may include functionality to provide various types of computer-implemented services. The computer-implemented services may include any number and type of computer-implemented services. The computer-implemented services may include, for example, database services, data processing services, electronic communication services, and/or any other services that may be provided using one or more computing devices. Other types of computer-implemented services may be provided by data processing system 100 without departing from embodiments disclosed herein.

To provide the computer implemented services, data processing systems may include any number of hardware components. For example, operation of the any number of hardware components may facilitate various functionalities of data processing system 100, thereby allowing data processing system 100 to provide the computer-implemented services. The hardware components of data processing system 100 may include, for example, electronics 102, power components 110, and/or thermal components 106. Each of these is discussed below.

Electronics 102 may include at least a portion of the any number of hardware components, and as noted above, may provide computer-implemented services. Hardware components of electronics 102 may be positioned on circuit cards and may generate heat while operating. Circuit cards may be pieces of circuit boards.

Electronics 102 and/or any other components of the any number of hardware components of data processing system 100 may be positioned in chassis 114. Chassis 114 may include an enclosure in which physical structures of electronics 102 (e.g., processors, memory, etc.), and/or other components of data processing system 100 may be positioned. For example, chassis 114 may facilitate placement and management of electronics 102 and/or other components (e.g., power components 110 and/or thermal components 106) in a computing environment such as those discussed below.

Power components 110 may power the any number of hardware components of data processing system 100. For example, power components 110 may be implemented using power supplies. Furthermore, operation of these power supplies may also contribute to the generation of heat. If left unregulated, this generation of heat may increase the likelihood of damage to data processing system 100.

To manage the heat generated by the various components, data processing system 100 may include a liquid cooling system that is at least partially housed by chassis 114. This liquid cooling system may include any number of cooling components such as thermal components 106, cooling tubes 108, liquid cooling block 112, and/or any other cooling components not shown in the system of FIG. 1.

Thermal components 106 may thermally manage any of the components of data processing system 100. For example, thermal components 106 may include thermal components such as cooling fans, coolant reservoirs and/or receiving elements for coolant, coolant (e.g., a cooling liquid), circulation pumps, manifolds or other types of flow control components, and/or other components to facilitate performance of liquid-based cooling of at least some of electronics 102. For example, thermal components 106 may be used with cooling tubes 108 and liquid cooling block 112, each of which is discussed below.

Liquid cooling block 112 may facilitate a dissipation of heat generated by, for example, electronics 102 by circulating the cooling liquid via cooling tubes 108. To provide its functionality, liquid cooling block 112 may operate as a heat sink for some electronic components (e.g., a portion of electronics 102). For example, liquid cooling block 112 may be placed with an electronic component to: (i) receive heat generated by the electronic component, and (ii) dissipate the received heat into cooling liquid circulated through liquid cooling block 112. While providing its functionality, a transference of at least a portion of the generated heat may be facilitated.

For example, the cooling liquid may be confined to a flow path that circulates through a loop of a liquid cooling system (e.g., cooling tubes 108, liquid cooling block 112, external components such as large-scale coolant chillers, flow controllers, etc.). The flow path may be placed in thermal communication with a hardware component of electronics 102, which may be generating the heat when the cooling liquid is flowing through a portion of the loop that is proximate to the hardware component. By being in this thermal communication, the cooling liquid may be heated while the heat generated by the hardware component is dissipated into the cooling liquid, thereby regulating the temperature of the hardware component.

The heated cooling liquid circulating through liquid cooling block 112 may then flow to another portion of the loop (e.g., external to data processing system 100, such as a large-scale chiller, not shown) in order to be cooled. Thus, the cooling liquid may be cyclically heated and cooled as the cooling liquid continues to flow through the loop, thereby contributing to the dissipation of heat generated by the any number of hardware components of electronics 102.

For example, the cooling liquid may be directed through an interior of liquid cooling block 112 and through a first portion of cooling tubes 108. Cooling tubes 108 may further facilitate the circulation by directing the cooling liquid, for example, to other cooling blocks proximate to other hardware components of electronics 102. In doing so, cooling of multiple hardware components of electronics 102 may be facilitated. To do so, cooling tubes 108 may include hollow, tubular structures in which liquid may flow through. For example, the cooling liquid, once cooled by external chillers, may then be further circulated through a second portion of cooling tubes 108 to direct the cooling liquid back through the liquid cooling block 112 to facilitate transference of additional heat generated by electronics 102.

However, by using the liquid cooling system discussed above, a likelihood of physically damaging the any number of hardware components (e.g., should a leak in liquid cooling block 112 and/or cooling tubes 108 occur) may be increased due to the presence of the cooling liquid. For example, if liquid cooling block 112 and/or cooling tubes 108 begin to leak, at least a portion of the cooling liquid may no longer be confined to the flow path that circulates through the loop of the liquid cooling system.

Consequently, should the any number of hardware components become exposed to liquid (e.g., the cooling liquid), functionality of the any number of hardware components may be negatively impacted, thereby negatively impacting an ability of data processing system 100 to provide the computer-implemented services.

In general, embodiments disclosed herein may provide methods, systems, and/or devices for managing leaks in a chassis of a data processing system to improve a likelihood that the data processing system is able to provide its computer-implemented services. To improve the likelihood that data processing system 100 is able to provide its computer-implemented services, data processing system 100 may include functionality to detect leaks using a leak detector (e.g., leak detector 104).

Leak detector 104 may be positioned internal to data processing system 100 and may be used to monitor portions of data processing system 100 in which leaks may occur (e.g., portions of data processing system 100 in which leaks are more likely to occur compared to other portions of data processing system 100). For example, leaks of the cooling liquid may occur at connection points of cooling tubes 108, such as cooling tube joint 116. Cooling tube joint 116 may include any type of connector and/or fitting used to connect a portion of cooling tube 108 to liquid cooling block 112. During operation of the liquid-cooling system over time, cooling tube joint 116 may fail to maintain a seal between the portion of cooling tube 108 and liquid cooling block 112. For example, cooling tube joint 116 may fail due to corrosion, wear and tear, improper installation, damage, and/or other reasons. As a result, the cooling liquid may begin to leak.

To detect the leak, therefore limiting damage to various components of data processing system 100 due to contact with the cooling liquid, leak detector 104 may include: (i) an electromagnetic stimulator, (ii) an electromagnetic detector, (iii) a modulator, and/or (iv) a management component. The electromagnetic stimulator may be adapted to illuminate a sample area with first electromagnetic radiation, and the first electromagnetic radiation may be adapted to cause a liquid (e.g., the cooling liquid) to generate second electromagnetic radiation if a liquid leak has occurred. The second electromagnetic may be generated by a dye included in the liquid for leak detection. The electromagnetic detector may be adapted to measure the second electromagnetic radiation to obtain at least one electromagnetic measurement. The at least one electromagnetic measurement may be used by the management component to determine whether the liquid leak has occurred. If the liquid leak has occurred, performance of a remediation action may be initiated to mitigate impacts of the liquid leak.

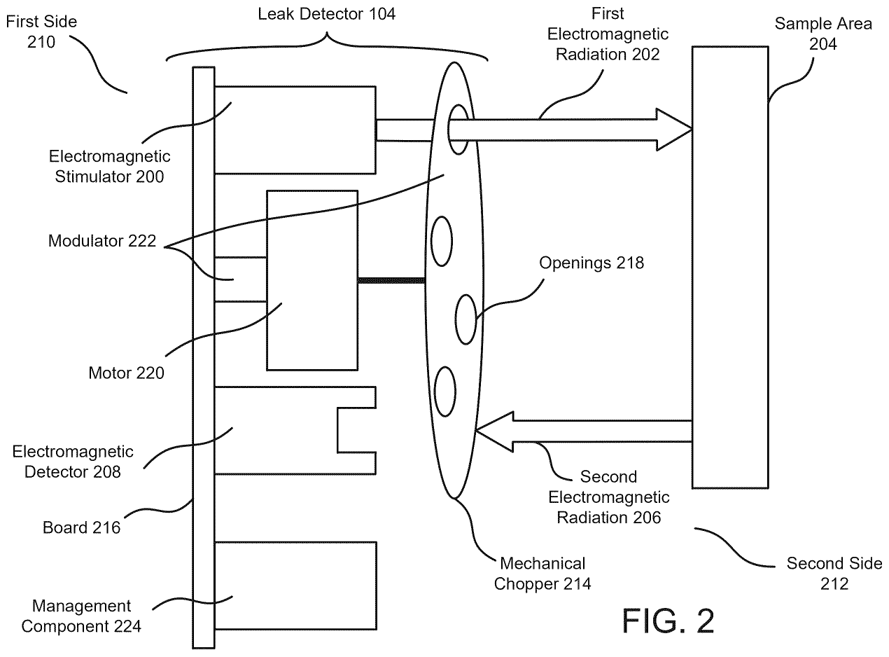

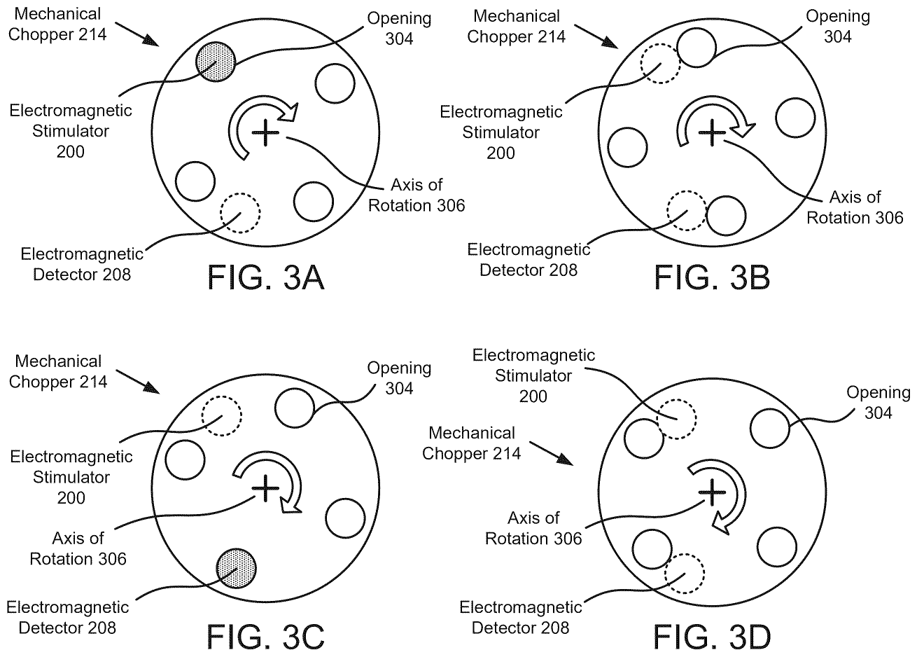

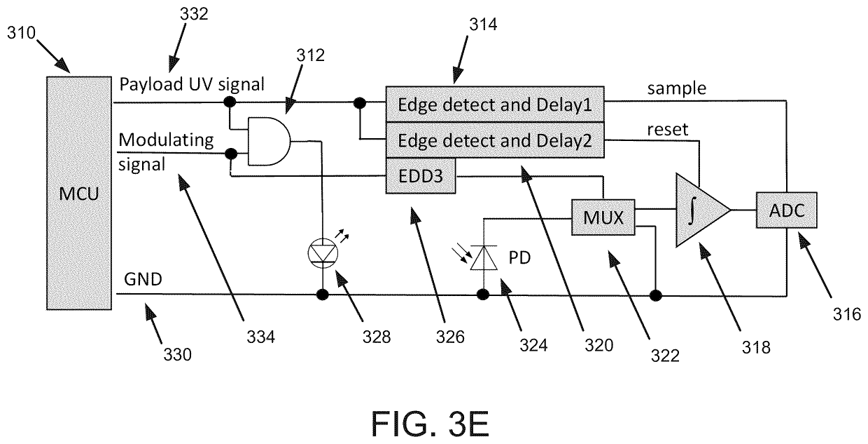

To improve a likelihood that the liquid leak is detected, leak detector 104 may also include a modulator. The modulator may be adapted to temporally manage the illuminating of the sample area and the measuring the second electromagnetic radiation so that the illuminating and the measuring occur asynchronously (e.g., mechanically controlled via a mechanical chopper and/or electronically controlled via an electrical circuit). The dye included in the liquid may be selected to have a time constant which allows for temporal separation between excitation of the dye by the first electromagnetic radiation and generation of the second electromagnetic radiation (e.g., fluorescence emission). Thus, the modulator may be used to manage a timing of illumination of the sample area and measurement collection so that each process occurs at a different point in time. For additional details regarding the modulator, refer to the description of FIGS. 2-3E.

By doing so, embodiments disclosed herein may improve a likelihood that the data processing system is able to provide computer-implemented services by increasing a likelihood of detecting a leak in the chassis of the data processing system. To do so, a modulator may be used to temporally separate illuminating a sample area with first electromagnetic radiation and measuring second electromagnetic radiation generated by the liquid leak (e.g., by a dye included in the liquid). As a result, an electromagnetic detector may be able to measure the second electromagnetic radiation with reduced interference from the first electromagnetic radiation (e.g., due to undesired scattering of the first electromagnetic radiation in the chassis). Consequently, the liquid leak may be detected, and actions may be performed so that additional leaked cooling liquid may be prevented from escaping into an interior of the chassis. In doing so, the likelihood of negatively impacting the hardware components, their functionalities, and the computer-implemented services that depend on these functionalities, may be reduced.

While illustrated in FIG. 1 with a limited number of specific components, a data processing system may include additional, fewer, and/or different components without departing from embodiments disclosed herein.

Turning to FIG. 2, a diagram illustrating leak detection in a chassis of a data processing system (e.g., data processing system 100) using leak detector 104 in accordance with an embodiment is shown. To detect the leak, leak detector 104 may include electromagnetic stimulator 200, electromagnetic detector 208, modulator 222, and management component 224. Each of these components is discussed below.

Electromagnetic stimulator 200 may be adapted to illuminate (e.g., irradiate) a sample area (e.g., sample area 204) with first electromagnetic radiation 202. Electromagnetic stimulator 200 may include any number and/or type of electromagnetic radiation sources adapted to generate first electromagnetic radiation 202 (e.g., light) of any wavelength and/or intensity. For example, electromagnetic stimulator 200 may include an ultraviolet (UV) light emitting diode (LED) lamp, and/or any other type of lamp.

Sample area 204 may include a portion of any size within the chassis which may have a risk of an occurrence of a liquid leak. For example, sample area 204 may include a liquid cooling tube joint and/or any other portion of the chassis for which leak detection is desired. In an instance of the occurrence of the liquid leak, sample area 204 may include at least a portion of the leaked liquid, such as droplets, particles, and/or any other portion of the liquid.

First electromagnetic radiation 202 may be adapted to cause the liquid to generate second electromagnetic radiation 206. For example, the liquid may include a dye. The dye may include any type and quantity of dye, such as fluorescent organic dyes, etc. The properties of first electromagnetic radiation 202 (e.g., wavelength, intensity, etc.) may be selected based on characteristics of the dye included in the liquid within sample area 204 to be detected. For example, the selected wavelength of first electromagnetic radiation 202 generated by electromagnetic stimulator 200 may interact with the dye in a desired manner. The interaction with the dye (e.g., excitation of electrons within the dye caused by absorbing a portion of first electromagnetic radiation 202) may cause the dye to generate second electromagnetic radiation 206 (e.g., fluorescence). Second electromagnetic radiation 206 may include electromagnetic radiation of any wavelength, intensity, and/or other characteristics based on properties of the dye which generates second electromagnetic radiation 206.

The dye included in the liquid may be selected so that the dye interacts with at least a portion of first electromagnetic radiation 202 at a first point in time, and generates, based on the interacting, second electromagnetic radiation 206 during at least a second point in time. For example, the dye may be selected to have time constants which allow second electromagnetic radiation 206 to be generated at least during the second point in time upon illumination with first electromagnetic radiation 202 during the first point in time. For example, the dye may have a first time constant, which may indicate an amount of time during illumination by first electromagnetic radiation 202 during which the dye is absorbing first electromagnetic radiation 202 (e.g., electrons within the dye are being promoted to their excited states). The dye may have a second time constant, which may indicate an amount during which second electromagnetic radiation 206 is being generated (e.g. as fluorescence decay as the excited electrons return to the ground state). The first time constant and the second time constant may or may not be the same. Thus, there may be temporal separation between absorption of first electromagnetic radiation 202 and emission of second electromagnetic radiation 206 by the dye. As a result, the dye may generate a portion of second electromagnetic radiation 206 after the liquid stops being illuminated with first electromagnetic radiation 202.

For example, sample area 204 may be illuminated with first electromagnetic radiation 202 for three milliseconds. After the three milliseconds of illumination, the dye included in the liquid may continue to generate second electromagnetic radiation 206 for five milliseconds. Therefore, in this example, if electromagnetic stimulator 200 stops illuminating sample area 204 after three milliseconds (e.g., electromagnetic stimulator 200 is shut off and/or blocked from illuminating sample area 204), the dye may continue to generate second electromagnetic radiation for five milliseconds.

At least a portion of second electromagnetic radiation 206 may be measured by electromagnetic detector 208 to obtain at least one electromagnetic measurement. Electromagnetic detector 208 may include any number and type of sensors adapted to measure electromagnetic radiation. For example, the sensors included as part of electromagnetic detector 208 may include photosensitive sensors adapted to measure wavelength, intensity, and/or other characteristics of electromagnetic radiation.

Second electromagnetic radiation 206 may be measured by electromagnetic detector 208 because second electromagnetic radiation 206 may be usable to determine (e.g., by management component 224) whether the liquid leak occurred. In contrast, first electromagnetic radiation 202 may not be usable to determine whether the liquid leak occurred, and thus, may not be intended to be measured. However, a portion of first electromagnetic radiation 202 may be collected by electromagnetic detector 208 due to, for example, scattering of first electromagnetic radiation 202 within the chassis.

Collection of first electromagnetic radiation 202 may negatively impact an ability of electromagnetic detector 208 to obtain the at least one electromagnetic measurement that is usable to determine whether the liquid leak occurred. For example, electromagnetic detector 208 may be adapted to measure first electromagnetic radiation 202 and second electromagnetic radiation 206 to generate a measurement signal. The measurement signal generated by electromagnetic detector 208 may not distinguish between contributions of first electromagnetic radiation 202 and second electromagnetic radiation 206 to the measurement signal. Further, first electromagnetic radiation 202 may have a higher intensity than second electromagnetic radiation 206 (e.g., by orders of magnitude), which may increase a difficulty in detecting second electromagnetic radiation 206. Thus, if the at least one electromagnetic measurement obtained by electromagnetic detector 208 includes contributions from both first electromagnetic radiation 202 and second electromagnetic radiation 206, there may be a reduced likelihood of determining whether the liquid leak occurred.

For example, first electromagnetic radiation 202 may include ultraviolet (UV) light adapted to cause the dye to generate green light (e.g., second electromagnetic radiation 206). Electromagnetic detector 208 may include a photosensitive sensor which is able to measure both the UV light and the green light. While illuminating sample area 204, some of the UV light may reach electromagnetic detector 208 due to scattering. As a result, if both the UV light and the green light are measured by electromagnetic detector 208, the occurrence of the liquid leak may be unable to be determined.

Other interactions between first electromagnetic radiation 202 and electromagnetic detector 208 may also impact an ability of electromagnetic detector 208 to obtain the at least one electromagnetic measurement. For example, collection of first electromagnetic radiation 202 by electromagnetic detector 208 may result in overexposure of the photosensitive sensors, which may result in damage, reduced sensitivity, and/or other negative impacts on electromagnetic detector 208 over time.

To improve a likelihood that the occurrence of the liquid leak is able to be detected, leak detector 104 may include modulator 222. Modulator 222 may be adapted to temporally manage the illuminating of sample area 204 by electromagnetic stimulator 200 and the measuring second electromagnetic radiation 206 by electromagnetic detector 208 so that the illuminating and the measuring occur asynchronously. For example, modulator 222 may be adapted to cause the illuminating to occur at a first point in time, and the measuring to occur at a second point in time. As a result of asynchronous illuminating and measuring, measurement signal generated by electromagnetic detector 208 may have a reduced level of contribution by first electromagnetic radiation 202. For example, the measuring may occur after first electromagnetic radiation 202 decays, so that portions of first electromagnetic radiation 202 may not reach electromagnetic detector 208 while electromagnetic detector 208 is obtaining measurements. Consequently, the likelihood of detecting the liquid leak may be improved.

To do so, modulator 222 may physically and/or electronically temporally manage the illuminating of sample area 204 by electromagnetic stimulator 200 and the measuring second electromagnetic radiation 206 by electromagnetic detector 208. To do so physically, modulator 222 may include mechanical chopper 214.

Mechanical chopper 214 may include a device that periodically interrupts illumination of sample area 204 by first electromagnetic radiation 202 by physically blocking electromagnetic stimulator 200 (e.g., rather than powering off electromagnetic stimulator 200). Mechanical chopper 214 may include any type and quantity of choppers, such as a rotating disc chopper, and may be of any size or shape. While shown in FIG. 2 as being disc shaped, it will be appreciated that mechanical chopper 214 may be of any other shape without departing from embodiments disclosed herein. Refer to the description of FIGS. 3A-3D for additional details regarding mechanical chopper 214.

Mechanical chopper 214 may include: (i) at least one opening (e.g., openings 218) adapted to allow first electromagnetic radiation 202 and second electromagnetic radiation 206 to traverse mechanical chopper 214, and/or (ii) a motor (e.g., motor 220) adapted to rotate mechanical chopper 214 to temporally manage the illuminating and the measuring.

Openings 218 may include holes of any size and shape through mechanical chopper 214. For example, openings 218 may be rectangular, circular, and/or any other shape. Openings 218 may allow electromagnetic radiation to enter and/or exit mechanical chopper 214. Consequently, the electromagnetic radiation may pass through mechanical chopper 214 via openings 218. Openings 218 may be positioned so that first electromagnetic radiation 202 and second electromagnetic radiation 206 do not traverse mechanical chopper 214 at a same point in time. Refer to the description of FIGS. 3A-3D for additional details.

In contrast, other portions of mechanical chopper 214 which do not include openings 218 may block and/or otherwise prevent electromagnetic radiation from passing through mechanical chopper 214. For example, mechanical chopper 214 may include a coating adapted to absorb or reflect electromagnetic radiation. In doing so, mechanical chopper 214 may be used to control passage of electromagnetic radiation from a source of the electromagnetic radiation to a receiver of the electromagnetic radiation.

Mechanical chopper 214 may include first side 210 and second side 212. First side 210 may include a portion of mechanical chopper 214 positioned facing away from sample area 204. Electromagnetic stimulator 200 and electromagnetic detector 208 may be positioned with first side 210. Second side 212 may include a portion of mechanical chopper 214 positioned facing toward sample area 204. Based on the positioning, first electromagnetic radiation 202 may enter openings 218 in mechanical chopper 214 from first side 210 to reach sample area 204, and second electromagnetic radiation 206 may enter openings 218 in mechanical chopper 214 from second side 212 to reach electromagnetic detector 208.

To temporally manage the illuminating and the measuring, mechanical chopper 214 may include motor 220. Motor 220 may include an electric motor used to rotate and/or otherwise physically move mechanical chopper 214 at any rate. For example, motor 220 may connect to mechanical chopper 214, and may rotate mechanical chopper 214 around an axis of rotation. Motor 220 may be phase locked to first electromagnetic radiation 202 (and/or asynchronous operation may be facilitated by signaling architecture). By rotating (and/or otherwise moving) mechanical chopper 214 using motor 220, a timing in which first electromagnetic radiation 202 and/or second electromagnetic radiation 206 traverses mechanical chopper 214 through openings 218 may be controlled (e.g., which may be defined by a rate of rotation). Refer to the description of FIGS. 3A-3D for additional details regarding rotation of mechanical chopper 214.

While described with respect to the timing in which first electromagnetic radiation 202 and/or second electromagnetic radiation 206 traverses mechanical chopper 214 through openings 218 being controlled by motor 220, it will be appreciated that the timing may also be controlled by a geometry of mechanical chopper 214 (e.g., via a positioning of openings 218).

Once obtained by electromagnetic detector 208, the at least one electromagnetic measurement may be provided to management component 224. Management component 224 may be adapted to determine whether the liquid leak within the chassis has occurred based on the at least one electromagnetic measurement. Management component 224 may include a management controller and/or other device of any type and/or including any quantity of components, such as a processing unit, that: (i) controls and/or monitors electromagnetic detector 208, (ii) obtains information regarding a status of electromagnetic detector 208, (iii) analyzes data (e.g., measurements) obtained by electromagnetic detector 208, and/or (iv) otherwise manages electromagnetic detector 208.

Management component 224 may make the determination regarding whether the liquid leak occurred by analyzing the at least one electromagnetic measurement. Analyzing the at least one electromagnetic measurement may include: (i) obtaining an electromagnetic spectrum using the at least one electromagnetic measurement, and/or (ii) comparing the electromagnetic spectrum to a known electromagnetic spectrum of the liquid. For example, a dye in a cooling liquid may generate second electromagnetic radiation 206 with a known electromagnetic spectrum when illuminated with first electromagnetic radiation 202. If the electromagnetic spectrum obtained based on the at least one electromagnetic measurement matches the known electromagnetic spectrum for the dye, management component 224 may determine that the liquid leak has occurred. If the electromagnetic spectrum obtained based on the at least one electromagnetic measurement does not match the known electromagnetic spectrum for the dye, management component 224 may determine that the liquid leak has not occurred.

If management component 224 determines that the liquid leak has occurred, management component 224 may initiate performance of a remediation action to mitigate impacts of the liquid leak. For example, management component 224 may: (i) notify a user of the data processing system via a graphical user interface that the liquid leak has occurred, (ii) generate an auditory notification indicating that the liquid leak has occurred, (iii) power off a portion of the hardware components of the data processing system (e.g., fans may be powered off to reduce spreading of the leak), and/or (iv) initiate performance of other remediation actions.

Any components of leak detector 104 may be positioned within the chassis of the data processing system using board 216. Board 216 may include any type of printed circuit board (e.g., flex, semi-flex) usable to provide a physical base for mounting and operably connecting the components of leak detector 104. For example, board 216 may allow components to be operably connected to management component 224 to allow management component 224 to manage operation of leak detector 104.

While illustrated in FIG. 2 with a limited number of specific components, a system may include additional, fewer, and/or different components without departing from embodiments disclosed herein.

Turning to FIGS. 3A-3D, diagrams illustrating a front view of a mechanical chopper of a modulator (e.g., mechanical chopper 214) in accordance with an embodiment are shown. Mechanical chopper 214 may be a part of a leak detector (e.g., leak detector 104) used to manage leaks in a chassis of a data processing system (e.g., data processing system 100 shown in FIG. 1). As discussed, the leak detector may include electromagnetic stimulator 200 which may generate first electromagnetic radiation, and electromagnetic detector 208 which may measure second electromagnetic radiation.

Each of FIGS. 3A-3D may show a positioning of mechanical chopper 214 at a different point in time. The different points in time may be sequential. For example, FIG. 3A may represent a first point in time, FIG. 3B may represent a second point in time following the first point in time, etc.

In FIGS. 3A-3D, circles outlined with solid lines may be used to represent openings in mechanical chopper 214 (e.g., opening 304). Circles outlined with dashed lines may be used to represent portions of the leak detector which are blocked by mechanical chopper 214 (e.g., electromagnetic radiation may be unable to traverse mechanical chopper 214 when the portions are blocked). Circles filled with a black dotted infill may represent portions of the leak detector which are able to provide and/or receive electromagnetic radiation.

For example, the portions of mechanical chopper 214 labeled electromagnetic stimulator 200 and electromagnetic detector 208 may represent a positioning of electromagnetic stimulator 200 and electromagnetic detector 208 behind mechanical chopper 214. Mechanical chopper 214 may rotate over time, and electromagnetic stimulator 200 and electromagnetic detector 208 may remain stationary over time. At a point in time when an opening positioned with electromagnetic stimulator 200 is shown filled with the black dotted infill, first electromagnetic radiation may traverse mechanical chopper 214 (e.g., may reach the sample area). Likewise, at a point in time when an opening positioned with electromagnetic detector 208 is shown filled with the black dotted infill, second electromagnetic radiation may traverse mechanical chopper 214 (e.g., may reach electromagnetic detector 208).

Mechanical chopper 214, as discussed, may be used as part of a modulator to physically temporally manage: (i) illuminating of a sample area by electromagnetic stimulator 200 using the first electromagnetic radiation, and (ii) measuring the second electromagnetic radiation generated by liquid (e.g., generated by a dye included in the liquid). To do so, mechanical chopper 214 may include openings.

The openings may be similar to openings 218 described in FIG. 2. The openings may be positioned so that the first electromagnetic radiation and the second electromagnetic radiation do not traverse mechanical chopper 214 at a same point in time (e.g., based on a spacing between the openings, a positioning of electromagnetic stimulator 200 and electromagnetic detector 208 with respect to the openings, etc.). While shown in FIGS. 3A-3D as having four openings, it will be appreciated that mechanical chopper 214 may have any number of openings of any shape and size without departing from embodiments disclosed herein. For example, the openings may include opening 304.

Mechanical chopper 214 may include a motor (not shown, refer to FIG. 2) which may rotate mechanical chopper 214 around axis of rotation 306. For example, a direction of rotation about axis of rotation 306 may be illustrated in FIGS. 3A-3D with an arrow.

In FIG. 3A, mechanical chopper 214 may be positioned so that an opening allows the first electromagnetic radiation generated by electromagnetic stimulator 200 to traverse mechanical chopper 214. Electromagnetic detector 208 may be blocked by mechanical chopper 214, and may therefore be unable to receive the second electromagnetic radiation.

In FIG. 3B, mechanical chopper 214 may be positioned so that an opening blocks both electromagnetic stimulator 200 and electromagnetic detector 208. The first electromagnetic radiation and the second electromagnetic radiation may be unable to traverse mechanical chopper 214.

In FIG. 3C, mechanical chopper 214 may be positioned so that electromagnetic stimulator 200 is blocked and the first electromagnetic radiation is unable to traverse mechanical chopper 214. An opening may allow the second electromagnetic radiation generated by the liquid to traverse mechanical chopper 214 and be measured by electromagnetic detector 208.

In FIG. 3D, similar to FIG. 3B, mechanical chopper 214 may be positioned so that an opening blocks both electromagnetic stimulator 200 and electromagnetic detector 208. The first electromagnetic radiation and the second electromagnetic radiation may be unable to traverse mechanical chopper 214.

The rotation of mechanical chopper 214 may continue for any number of cycles and at any rate of rotation. In doing so, a timing of illuminating the sample area and measuring the second electromagnetic radiation generated by the liquid may be controlled.

While illustrated in FIGS. 3A-3D with a limited number of specific components, a system may include additional, fewer, and/or different components without departing from embodiments disclosed herein.

Turning to FIG. 3E, an electrical schematic diagram illustrating an electronically controlled modulator in accordance with an embodiment is shown. The diagram may show an electrical circuit adapted to temporally manage: (i) illuminating of a sample area by an electromagnetic stimulator (e.g., 328) with first electromagnetic radiation, and (ii) measuring second electromagnetic radiation generated by a liquid (e.g., a dye included in the liquid) using an electromagnetic detector (e.g., 324) such as a photodiode (PD). Refer to the description of FIG. 2 for additional details regarding the electromagnetic stimulator and/or the electromagnetic detector.

To do so, the modulator may include functionality to: (i) selectively power electromagnetic stimulator 328, and (ii) configure operation of electromagnetic detector 324. To selectively power electromagnetic stimulator 328, the electrical circuit may include a microcontroller unit (MCU) (e.g., 310).

MCU 310 may be implemented, for example, using a system on a chip or other type of computing device. MCU 310 may provide various management functionalities for the modulator. For example, MCU 310 may manage a timing of operations, such as managing when electromagnetic stimulator 328 is powered on or off. MCU 310 may do so by controlling output signal to activate or deactivate electromagnetic stimulator 328.

The output signal may include payload UV signal (e.g., 332) and modulating signal (e.g., 334). Payload UV signal 332 may include signal to power on electromagnetic stimulator 328 (e.g., a UV LED light). For example, MCU 310 may output payload UV signal 332 to power electromagnetic stimulator 328 for a duration of time over which any number of periods of illumination may occur. To control the periods of illumination, MCU 310 may output modulating signal 334. Modulating signal 334 may also include signal to power on electromagnetic stimulator 328. However, modulating signal 334 may be used to regulate increments of illumination over the duration of time that payload UV signal 332 is output by MCU 310.

Payload UV signal 332 and modulating signal 334 may be received by a logic gate (e.g., 312). Logic gate 312, for example, may include an AND logic gate which outputs one signal to activate electromagnetic stimulator 328 upon receiving both payload UV signal 332 and modulating signal 334. As a result, MCU 310 may use the payload UV signal output and the modulating signal output to temporally manage the illuminating of the sample area by electromagnetic stimulator 328. A timing of the illumination controlled by MCU 310 may be based on characteristics of the dye in the liquid to be detected (e.g., the dye time constant).

The modulator may also be adapted to configure operation of electromagnetic detector 324 (or related components such as multiplexer 322) to temporally manage the measuring of the second electromagnetic radiation generated by the liquid. For example, the modulator may selectively gate output generated by electromagnetic detector 324 based on the selective powering of electromagnetic stimulator 328 so that measuring of the second electromagnetic radiation occurs when electromagnetic stimulator 328 is powered off. By doing so, the sample area may be illuminated with the first electromagnetic radiation at a first point in time, and the second electromagnetic radiation generated by the liquid may be measured at a second point in time. Thus, a likelihood that the first electromagnetic radiation impacts measurements made by electromagnetic detector 324 may be reduced.

To configure the operation of electromagnetic detector 324 (or related components) based on the selective powering of electromagnetic stimulator 328, the circuit may include edge detect and delay (EDD) 1-3 (e.g., 314, 320, 326). While shown in FIG. 3E as having three EDDs, it will be appreciated that the circuit may include any number of EDDs and/or the EDDs may be omitted without departing from embodiments disclosed herein.

The EDDs may be used to synchronize signals, trigger events, and/or respond to changes in input states. For example, the EDDs may be used to detect signal transitions and introduce controlled delays to filter out noise that may be misinterpreted by the system as a valid signal change.

EDD3 (e.g., 326) may be used to configure settings of a multiplexor (MUX) (e.g., 322). MUX 322 may include a device which selects an input signal from a plurality of input signals and propagates the selected input signal to a single output. For example, when electromagnetic stimulator 328 is powered on, EDD3 326 may configure MUX 322 so that output of electromagnetic detector 324 based on signal measured by electromagnetic detector 324 is not propagated to other components used to quantify the signal. In doing so, unwanted signal obtained when electromagnetic stimulator 328 is powered on may be diverted away (e.g., from 318, see below) and not measured. Conversely, when electromagnetic stimulator 328 is powered off, EDD3 326 may configure MUX 322 so that signal measured by the electromagnetic detector is propagated (e.g., to 318). Thus, the configuration of MUX 322 by EDD3 326 may be used to control a timing of when MUX 322 propagates the output based on a signal detected by electromagnetic detector 324.

The output propagated by MUX 322 may be input into other components used to quantify the signal measured by electromagnetic detector 324. For example, the other components may include an operational amplifier (op-amp) (e.g., 318). Op-amp 318 may be used to perform various signal processing tasks, such as signal amplification, signal integration, signal filtering, etc. For example, op-amp 318 may be used to integrate signal from electromagnetic detector 324. The signal measured by electromagnetic detector 324 may, for example, be of low intensity (e.g., the signal may be weak) due to a short duration of generation of the second electromagnetic radiation. Op-amp 318 may, therefore, be used to integrate signal over multiple measurement cycles (e.g., multiple periods of sample area illumination and measurement collection) so that the signal is able to be measured by the analog-to-digital converter (ADC) (e.g., 316).

ADC 316 may convert analog signal (e.g., electrical signal) into a digital signal representation, which may then be processed. In doing so, measurements obtained by electromagnetic detector 324 may be used by a management component of the leak detector (refer to the description of FIG. 2) to determine whether a liquid leak has occurred.

Components of the circuit may also be connected to ground (GND) 330. GND 330 may function as a reference point for measuring voltage of other components in the circuit. GND 330 may also provide a path for current to return to a power source after completing the circuit.

While illustrated in FIG. 3E with a limited number of specific components, a system may include additional, fewer, and/or different components without departing from embodiments disclosed herein. For example, any number of components, such as logic gate 312, EDDs 1-3 (e.g., 314, 320, 326), op-amp 318, etc. may be implemented as part of firmware included in MCU 310.

Any of the operations performed by the components shown in FIG. 3E may be repeated, performed in different orders, and/or performed in parallel with or in a partially overlapping in a timely manner with other operations. For example, if op-amp 318 is implemented as part of the firmware of MCU 310, operations performed by op-amp 318 may be performed following operations performed by ADC 316.

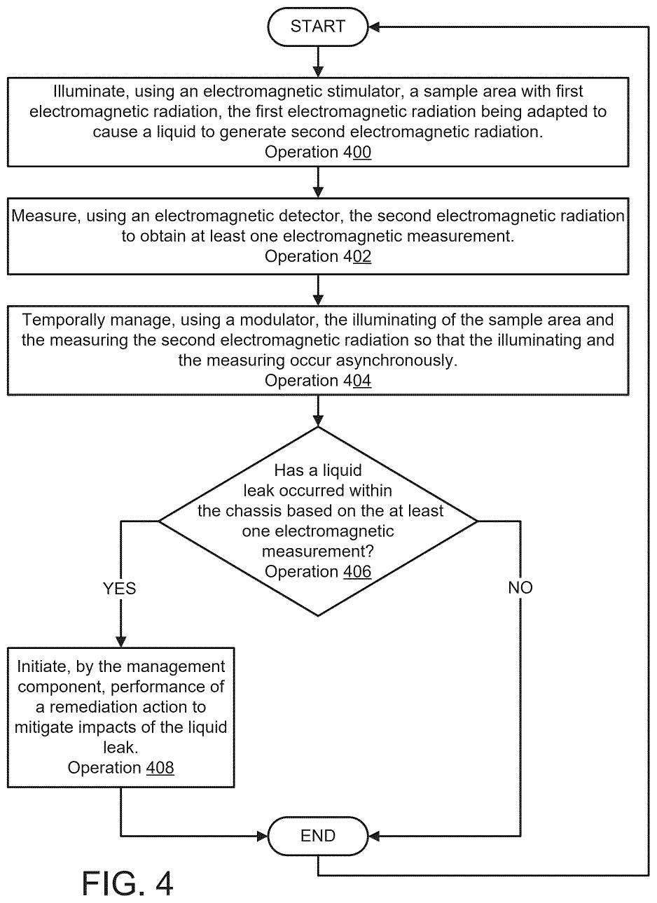

As discussed above, the components of FIGS. 1-3E may perform various methods to manage leaks in a chassis of a data processing system. FIG. 4 illustrates a method that may be performed by the components of the system of FIGS. 1-3E. In the diagram discussed below and shown in FIG. 4, any of the operations may be repeated, performed in different orders, and/or performed in parallel with or in a partially overlapping in a timely manner with other operations. The method described with respect to FIG. 4 may be performed by a data processing system, any component of a data processing system, and/or another device.

Turning to FIG. 4, a flow diagram illustrating a method in accordance with an embodiment is shown. The flow diagram may illustrate various operations performed while managing leaks in a chassis of a data processing system. The data processing system may be similar to the data processing system discussed with respect to FIGS. 1-3E.

At operation 400, a sample area may be illuminated with first electromagnetic radiation using an electromagnetic stimulator, the first electromagnetic radiation being adapted to cause a liquid to generate second electromagnetic radiation. Illuminating the sample area may include: (i) generating the electromagnetic radiation by the electromagnetic stimulator, (ii) directing the electromagnetic radiation towards the sample area (e.g., by positioning the electromagnetic stimulator with respect to the sample area to allow for illumination of the sample area), and/or (iii) other methods.

At operation 402, the second electromagnetic radiation may be measured using an electromagnetic detector to obtain at least one electromagnetic measurement. Measuring the second electromagnetic radiation may include: (i) receiving the second electromagnetic radiation by the electromagnetic detector, (ii) performing an analysis process by the electromagnetic detector to obtain the at least one electromagnetic measurement (e.g., determining an intensity of the second electromagnetic radiation for a wavelength and/or range of wavelengths to obtain the at least one electromagnetic measurement, using the intensity to obtain an electromagnetic spectrum for the second electromagnetic radiation), and/or (iii) other methods.

At operation 404, the illuminating of the sample area and the measuring the second electromagnetic radiation may be temporally managed using a modulator so that the illuminating and the measuring occur asynchronously. Temporally managing the illuminating and the measuring may include: (i) selectively powering, by the modulator, the electromagnetic stimulator (e.g., powering the electromagnetic stimulator in predefined time increments of on and off periods), (ii) configuring, by the modulator, the electromagnetic detector to measure the second electromagnetic radiation at a time when the electromagnetic stimulator is powered off (e.g., using a multiplexor in an electrical circuit), (iii) using a mechanical chopper to physically manage a timing of illumination and/or a timing of measurement collection (e.g., rotating a mechanical chopper so that the illuminating and the measuring occur asynchronously), and/or (iv) other methods.

At operation 406, a determination may be made by a management component regarding whether a liquid leak within the chassis has occurred based on the at least one electromagnetic measurement. Making the determination may include: (i) obtaining, by the management component, the electromagnetic spectrum of the sample area using the at least one electromagnetic measurement, (ii) comparing the electromagnetic spectrum of the sample area to a known electromagnetic spectrum for the liquid (e.g., a dye included in the liquid) to obtain a result, (iii) providing the electromagnetic spectrum to another entity and receiving an indication of whether the liquid leak has occurred in response, and/or (iv) other methods.

For example, if the result indicates that the electromagnetic spectrum of the sample area matches the known electromagnetic spectrum for the liquid, the management component may determine that the liquid leak has occurred. In another example, if the result indicates that the electromagnetic spectrum of the sample area does not match the known electromagnetic spectrum for the liquid, the management component may determine that the liquid leak has not occurred.

If it is determined that the liquid leak has occurred within the chassis (e.g., the determination is “Yes” at operation 406), then the method may proceed to operation 408.

At operation 408, the management component may initiate performance of a remediation action to mitigate impacts of the liquid leak. Initiating performance of the remediation action may include: (i) notifying a user of the data processing system via a graphical user interface that the liquid leak has occurred, (ii) powering a speaker to generate an auditory notification indicating that the liquid leak has occurred, (iii) powering off a portion of the hardware components of the data processing system (e.g., fans may be powered off to reduce spreading of the leak, electrical components may be powered off to reduce damage), and/or (iv) other methods.

The method may end following operation 408.

Returning to operation 406, if it is determined that the liquid leak has not occurred within the chassis (e.g., the determination is “No” at operation 406), then the method may end. The data processing system may continue to provide computer-implemented services as desired.

The method may subsequently be repeated any number of times. In doing so, the sample area may continue to be monitored for an occurrence of a liquid leak.

Thus, embodiments disclosed herein may address, among others, the technical challenge of mitigating risks associated with using a cooling liquid to provide thermal management services for a data processing system. To do so, the data processing system may include a leak detector, which may include a modulator adapted to temporally manage illuminating a sample area (e.g., where a liquid leak may occur) with first electromagnetic radiation by an electromagnetic stimulator and measuring second electromagnetic radiation generated by the liquid using an electromagnetic detector. As a result of the temporal management, a likelihood that the liquid leak may be detected may be improved (e.g., by mitigating negative impacts of undesired measuring of the first electromagnetic radiation by the electromagnetic detector). If the liquid leak has occurred, a remediation action may be performed. Thus, a likelihood of the liquid leak negatively impacting hardware functionality may be decreased and may in turn decrease a likelihood of negatively impacting computer-implemented services provided by the data processing system.

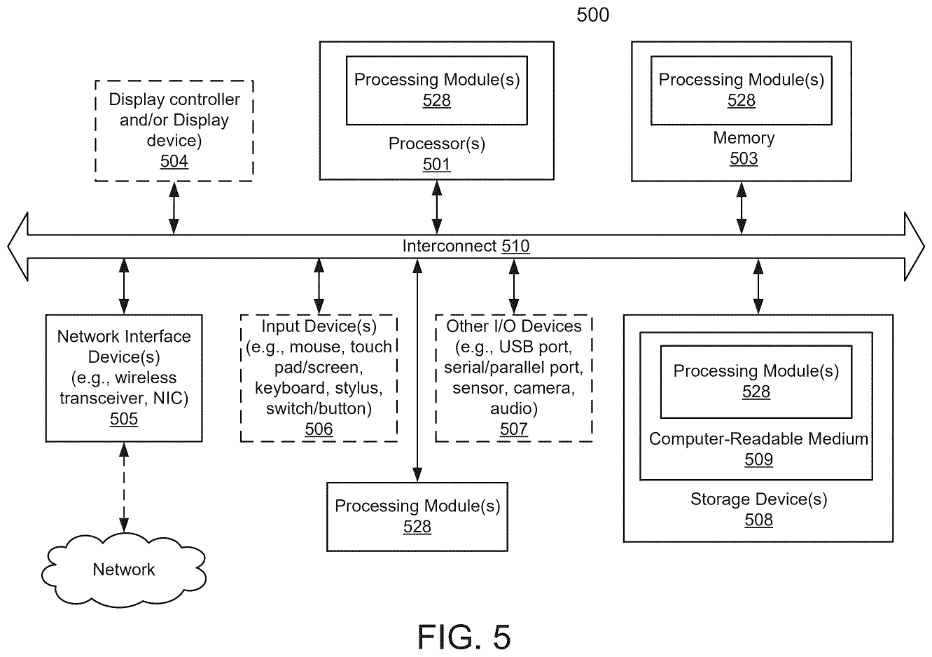

Any of the components and methods illustrated in FIGS. 1-4 may be implemented with one or more computing devices. Turning to FIG. 5, a block diagram illustrating an example of a data processing system (e.g., a computing device) in accordance with an embodiment is shown. For example, system 500 may represent any of data processing systems described above performing any of the processes or methods described above. System 500 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 500 is intended to show a high level view of many components of the computer system. However, it is to be understood that additional components may be present in certain implementations and furthermore, different arrangement of the components shown may occur in other implementations. System 500 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 500 includes processor 501, memory 503, and devices 505-507 via a bus or an interconnect 510. Processor 501 may represent a single processor or multiple processors with a single processor core or multiple processor cores included therein. Processor 501 may represent one or more general-purpose processors such as a microprocessor, a central processing unit (CPU), or the like. More particularly, processor 501 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 501 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 501, which may be a low power multi-core processor socket such as an ultra-low voltage processor, may act as a main processing unit and central hub for communication with the various components of the system. Such processor can be implemented as a system on chip (SoC). Processor 501 is configured to execute instructions for performing the operations discussed herein. System 500 may further include a graphics interface that communicates with optional graphics subsystem 504, which may include a display controller, a graphics processor, and/or a display device.

Processor 501 may communicate with memory 503, which in one embodiment can be implemented via multiple memory devices to provide for a given amount of system memory. Memory 503 may include one or more volatile storage (or memory) devices such as random access memory (RAM), dynamic RAM (DRAM), synchronous DRAM (SDRAM), static RAM (SRAM), or other types of storage devices. Memory 503 may store information including sequences of instructions that are executed by processor 501, or any other device. For example, executable code and/or data of a variety of operating systems, device drivers, firmware (e.g., input output basic system or BIOS), and/or applications can be loaded in memory 503 and executed by processor 501. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 500 may further include IO devices such as devices (e.g., 505, 506, 507, 508) including network interface device(s) 505, optional input device(s) 506, and other optional IO device(s) 507. Network interface device(s) 505 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 506 may include a mouse, a touch pad, a touch sensitive screen (which may be integrated with a display device of optional graphics subsystem 504), a pointer device such as a stylus, and/or a keyboard (e.g., physical keyboard or a virtual keyboard displayed as part of a touch sensitive screen). For example, input device(s) 506 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 507 may include an audio device. An audio device may include a speaker and/or a microphone to facilitate voice-enabled functions, such as voice recognition, voice replication, digital recording, and/or telephony functions. Other IO devices 507 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 507 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 510 via a sensor hub (not shown), while other devices such as a keyboard or thermal sensor may be controlled by an embedded controller (not shown), dependent upon the specific configuration or design of system 500.

To provide for persistent storage of information such as data, applications, one or more operating systems and so forth, a mass storage (not shown) may also couple to processor 501. In various embodiments, to enable a thinner and lighter system design as well as to improve system responsiveness, this mass storage may be implemented via a solid state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also a flash device may be coupled to processor 501, e.g., via a serial peripheral interface (SPI). This flash device may provide for non-volatile storage of system software, including a basic input/output software (BIOS) as well as other firmware of the system.

Storage device 508 may include computer-readable storage medium 509 (also known as a machine-readable storage medium or a computer-readable medium) on which is stored one or more sets of instructions or software (e.g., processing module, unit, and/or processing module/unit/logic 528) embodying any one or more of the methodologies or functions described herein. Processing module/unit/logic 528 may represent any of the components described above. Processing module/unit/logic 528 may also reside, completely or at least partially, within memory 503 and/or within processor 501 during execution thereof by system 500, memory 503 and processor 501 also constituting machine-accessible storage media. Processing module/unit/logic 528 may further be transmitted or received over a network via network interface device(s) 505.

Computer-readable storage medium 509 may also be used to store some software functionalities described above persistently. While computer-readable storage medium 509 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 528, components and other features described herein can be implemented as discrete hardware components or integrated in the functionality of hardware components such as ASICS, FPGAs, DSPs or similar devices. In addition, processing module/unit/logic 528 can be implemented as firmware or functional circuitry within hardware devices. Further, processing module/unit/logic 528 can be implemented in any combination hardware devices and software components.

Note that while system 500 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A data processing system, comprising:
a chassis;
an electromagnetic stimulator adapted to:
illuminate a sample area with first electromagnetic radiation, the first electromagnetic radiation adapted to cause a liquid to generate second electromagnetic radiation;
an electromagnetic detector adapted to:
measure the second electromagnetic radiation to obtain at least one electromagnetic measurement,
a modulator adapted to:
temporally manage the illuminating of the sample area and the measuring the second electromagnetic radiation so that the illuminating and the measuring occur asynchronously; and
a management component adapted to:
make a determination regarding whether a liquid leak within the chassis has occurred based on the at least one electromagnetic measurement; and
in an instance of the determination where the liquid leak has occurred:
initiate performance of a remediation action to mitigate impacts of the liquid leak.

2. The data processing system of claim 1, wherein the modulator comprises a mechanical chopper.

3. The data processing system of claim 2, wherein the mechanical chopper comprises:
at least one opening adapted to allow the first electromagnetic radiation and the second electromagnetic radiation to traverse the mechanical chopper; and
a motor adapted to rotate the mechanical chopper to temporally manage the illuminating and the measuring.

4. The data processing system of claim 3, wherein the mechanical chopper comprises:
a first side through which the first electromagnetic radiation enters the mechanical chopper; and
a second side through which the second electromagnetic radiation enters the mechanical chopper.

5. The data processing system of claim 4, wherein the electromagnetic stimulator and the electromagnetic detector are positioned with the first side of the mechanical chopper, and the sample area is positioned with the second side of the mechanical chopper.

6. The data processing system of claim 5, wherein the at least one opening is positioned so that the first electromagnetic radiation and the second electromagnetic radiation do not traverse the mechanical chopper at a same point in time.

7. The data processing system of claim 1, wherein the modulator is adapted to cause the illuminating to occur at a first point in time, and the measuring to occur at a second point in time.

8. The data processing system of claim 7, wherein the liquid comprises a dye adapted to:
interact with at least a portion of the first electromagnetic radiation at the first point in time; and
generate, based on the interacting, the second electromagnetic radiation during at least the second point in time.

9. The data processing system of claim 1, wherein the modulator is adapted to temporally manage the illuminating of the sample area and the measuring the second electromagnetic radiation by selectively powering the electromagnetic stimulator and configuring operation of the electromagnetic detector.

10. The data processing system of claim 9, wherein the modulator configures the operation of the electromagnetic detector based on the selective powering of the electromagnetic stimulator.

11. The data processing system of claim 1, wherein the electromagnetic detector is adapted to measure the first electromagnetic radiation and the second electromagnetic radiation to generate a measurement signal, the measurement signal not distinguishing between contributions of the first electromagnetic radiation and the second electromagnetic radiation to the generated measurement signal.

12. The data processing system of claim 11, wherein the illuminating and the measuring occur asynchronously to obtain an instance of the generated measurement signal that has a reduced level of contribution by the first electromagnetic radiation.

13. A method for managing leaks in a chassis of a data processing system, the method comprising:
illuminating, using an electromagnetic stimulator, a sample area with first electromagnetic radiation, the first electromagnetic radiation being adapted to cause a liquid to generate second electromagnetic radiation;
measuring, using an electromagnetic detector, the second electromagnetic radiation to obtain at least one electromagnetic measurement,
temporally managing, using a modulator, the illuminating of the sample area and the measuring the second electromagnetic radiation so that the illuminating and the measuring occur asynchronously;
making, by a management component, a determination regarding whether a liquid leak within the chassis has occurred based on the at least one electromagnetic measurement; and
in an instance of the determination where the liquid leak has occurred:
initiating, by the management component, performance of a remediation action to mitigate impacts of the liquid leak.

14. The method of claim 13, wherein the modulator comprises a mechanical chopper.

15. The method of claim 14, wherein the mechanical chopper comprises:
at least one opening adapted to allow the first electromagnetic radiation and the second electromagnetic radiation to traverse the mechanical chopper; and
a motor adapted to rotate the mechanical chopper to temporally manage the illuminating and the measuring.

16. The method of claim 15, wherein the mechanical chopper comprises:
a first side through which the first electromagnetic radiation enters the mechanical chopper; and
a second side through which the second electromagnetic radiation enters the mechanical chopper;

17. The method of claim 16, wherein the electromagnetic stimulator and the electromagnetic
detector are positioned with the first side of the mechanical chopper. and the sample area is positioned with the second side of the mechanical chopper,

18. The method of claim 17, wherein the at least one opening is positioned so that the first electromagnetic radiation and the second electromagnetic radiation do not traverse the mechanical chopper at a same point in time.

19. The method of claim 13, wherein the modulator is adapted to cause the illuminating to occur at a first point in time, and the measuring to occur at a second point in time.

20. The method of claim 19, wherein the liquid comprises a dye adapted to:
interact with at least a portion of the first electromagnetic radiation at the first point in time; and
generate, based on the interacting, the second electromagnetic radiation during at least the second point in time.
